(19) United States
(12) Patent Application Publication
(10) Pub. No.: US 2005/0112505 A1
(43) Pub. Date: May 26, 2005

(54) Field-assisted micro- and nano-fabrication method

(76) Inventors: Wen C. Huang, Fargo, ND (US); Bor Z. Jang, Fargo, ND (US)

Correspondence Address: Wen C. Huang, 2902, 28th Ave., SW, Fargo, ND, 58103, US

(21) Appl. No.: 10/720,891

(22) Filed: Nov. 25, 2003

(51) Int. Cl. G03F 7/16

(52) U.S. Cl. 430/315; 430/935

(57) ABSTRACT

A direct-write micro- or nano-lithography method for depositing a functional material with a preferred orientation onto a target surface. The method includes the steps of (1) forming a precursor fluid to the functional material; (2) operating a sub-micrometer tip to discharge, on contact, the precursor fluid onto the target surface so as to produce a desired pattern of deposited functional material in sub-micrometer dimensions; and (3) during the pattern-producing step, subjecting the deposited material to a highly localized electric or magnetic field for attaining a preferred orientation in at least a portion of the functional material. The method is particularly useful for microfabrication, nanotechnology, and molecular electronics.

### FIELD OF INVENTION

This invention relates to methods of micro-fabrication and nano-fabrication. Specifically, the invention provides a method for directly depositing a thin pattern of functional molecules with a controlled or preferred orientation onto a substrate under the influence of a strong, localized electric or magnetic field. The method is particularly useful for making a micro-electro-mechanical system (MEMS), micro-sensor, and other micro-devices featuring a sub-micrometer-sized molecular or polymeric material element that exhibit a useful function such as piezoelectric, pyroelectric, ferro-electric, ferromagnetic, and non-linear optic properties.

### BACKGROUND

Lithography is one of the key processing methods in the fabrication of semiconductor integrated electrical, optical, magnetic, and/or micro-mechanical circuits and micro-devices. Lithography creates a pattern in a resist on a substrate so that, in subsequent steps, the pattern is replicated in the substrate or in another material which is added onto the substrate. A typical lithography process for the integrated circuits (IC) fabrication involves exposing a resist with a beam of energetic particles which are electrons, photons, or ions, by either passing a flood beam through a mask or scanning a focused beam. The particle beam changes the chemical structure of the exposed area of the resist layer. In subsequent etching, either the exposed area or the unexposed area of the resist will be removed to recreate the patterns. The resolution of a lithography method is limited by the wavelength of the particles, the particle scattering in the resist and the substrate, and the properties of the resist.

The micro-fabrication industry has a continuing interest and need in lithography methods that are capable of producing patterns of progressively smaller sizes. An urgent need exists for the development of low-cost technologies for mass producing sub-50 nm or smaller structures. This need is prompted by the industry's desire to further reduce the size of ICs and other miniature devices or to dramatically increase the number of functional elements (e.g., transistors) per unit area or volume of a device.

Electron beam lithography (EBL) has demonstrated a 10 nm lithography resolution. However, it has not been economically practical to use EBL for mass production of sub-50 nm structures due to its inherent low throughput in a serial process. X-ray lithography can have a high throughput and has demonstrated a 50 nm lithography resolution. However, the X-ray lithography tools are rather expensive and their ability for mass-producing sub-50 nm structures has yet to be demonstrated. Several negative printing techniques are also available that rely on scanning probe instruments, electron beams, or molecular beams to pattern substrates using self-assembling monolayers and other organic materials as resist layers.

Imprinting techniques using compressive molding of thermoplastic polymers are low-cost mass-production technology. Features with sizes greater than 1 micrometer have been routinely imprinted in plastics. Examples include compact disks which are based on imprinting of polycarbonate and micro-mechanical parts containing polymethyl methacrylate (PMMA) structures with a feature size on the order of 10 micrometers. However, the use of imprint technology to provide 25 nm structures with high aspect ratios had not been achieved until the nano-imprint technology was developed (see, for instance, S. Y. Chou, “Nanoimprint lithography,” U.S. Pat. No. 5,772,905, Jun. 30, 1998; S. Y. Chou, U.S. Pat. No. 6,309,580 (Oct. 30, 2001); U.S. Pat. No. 6,518,189 (Feb. 11, 2003); U.S. Pat. No. 6,482,742 (Nov. 19, 2002); and S. Y. Chou, C. Keimel, and J. Gu, “Ultrafast and direct imprint of nanostructures in silicon,” Nature, 417 (Jun. 20, 2002) 835-837.). This method is potentially a high throughput mass production lithography method that has the ability to produce features as small as 10 nm.

The dip pen nano-lithography (DPN) technique utilizes a scanning probe microscope (SPM) tip (e.g., an atomic force microscope (AFM) tip) as a “nib” or “pen,” a solid-state substrate (e.g., gold) as “paper,” and molecules with a chemical affinity for the solid-state substrate as “ink.” Capillary transport of molecules from the tip to the solid substrate is used in DPN to directly write patterns consisting of a relatively small collection of molecules in sub-micrometer or nanometer dimensions. DPN can deliver relatively small amounts of a molecular substance to a substrate in a nano-lithographic fashion that does not rely on a resist, a stamp, complicated processing methods, or sophisticated noncommercial instrumentation. (Please see C. A. Mirkin, R. Piner, and S. Hong, “Methods utilizing scanning probe microscope tips and products therefor or products thereby, U.S. Pat. No. 6,635,311, Oct. 23, 2003; K. H. Kim, et al., “Massively parallel multi-tip nanoscale writer with fluidic capabilities—Fountain pen nanolithography,” in 2003 SEM Annual Conf. on Experimental and Applied Mechanics, Soc. Of Exp. Mech., Jun. 2-4, 2003, Charlotte, N.C.; M. Zhang, et al. “A MEMS nanoplotter with high-density dip-pen nanolithography probe arrays,” Nanotechnology, 13 (2002) 212-217.) It may be noted that the nano-imprint and other micro-contact methods can deposit an entire pattern or series of patterns on a substrate of interest in one step. This is an advantage over a serial technique like DPN. However, DPN can be advantageous if one is trying to selectively place different types of molecules at specific sites within a particular type of nanostructure. In this regard, DPN and nano-imprint techniques may be considered as complementary to each other.

In order to miniaturize and integrate traditional microelectronic elements and functionally responsive elements (e.g., photonic and piezoelectric) together, a new sector of micro-electronics industry, known as micro-electro-mechanical systems (MEMS), has started to emerge. MEMS are finding ever broadening applications, including complex sensor and actuator arrays that go into devices such as air bag activators, piezo-electric inkjet print-heads, and other miniature smart material devices. Many of the current and future micro-devices, including MEMS, contain sub-micrometer or nanometer-size structures (phases, domains, elements, etc.) that exhibit desirable functions, e.g., ferro-magnetic, piezoelectric, pyroelectric, photonic, mechano-chemical, thermo-electric, non-linear optic, etc. These structures are typically characterized by having preferred molecular orientations. The current micro- or nano-lithography methods, including nano-imprint and dip pen nano-lithography, are not capable of creating micro or nano structures with well-controlled or pre-designed molecular orientations. Disclosed in one of our commonly own patent applications (W. C. Huang, “Method and Apparatus for Direct-Write of Functional Materials with a Controlled Orientation,” U.S. patent Pending, Ser. No. 10/353,667, Jan. 30, 2003) were a direct-write method and apparatus for depositing a functional material with a preferred orientation onto a target surface. The method comprises (a) operating an inkjet printhead-like dispensing device to discharge and deposit a precursor fluid onto a target surface in a substantially point-by-point manner and at least partially removing the liquid component of the precursor fluid from the deposited fluid to form a thin layer of the functional material which is substantially solidified; and (b) during the liquid-removing step, subjecting the deposited fluid to a highly localized electric or magnetic field for poling until a preferred orientation is attained in the deposited functional material. Since an inkjet printhead-like device is normally limited to dispensing of liquid droplets of 15 μm or larger in diameter, this method is not capable of performing nano-fabrication to produce nanometer-scale structures although some nanometer-scale domains with a preferred orientation can be created within a super-micrometer-scale structure (>10 μm).

Therefore, it is an object of the present invention to provide an improved micro- or nano-lithography method for creating sub-micrometer or nanometer-size self-assembled monolayers with controlled orientations.

It is another object of the present invention to provide a dip-pen nano-lithography method for direct-write of functional elements using a sub-micrometer tip under the influence of a strong, highly localized electric or magnetic field.

It is a specific object of the present invention to provide an improved dip pen-type nano-lithography method for direct-write of functional elements under the influence of a strong, highly localized electric or magnetic field generated by using a split-tip proximal probe or a pair of nanometer-size tips.

### SUMMARY OF THE INVENTION

One preferred embodiment of the present invention is a dip pen-based micro- or nano-fabrication method capable of directly depositing a functional material with a preferred orientation in the form of a patterned thin film (e.g., a self-assembled monolayer, SAM) onto a target surface. The method includes the following steps: (1) forming a precursor fluid to the functional material with the fluid containing a liquid component; (2) operating a sub-micrometer tip to discharge the precursor fluid onto the target surface, by bringing the tip to contact the target surface, so as to produce a desired pattern of deposited functional material in sub-micrometer dimensions; and (3) during the pattern-producing step, subjecting the deposited material to a highly localized electric or magnetic field for attaining a preferred orientation in at least a portion of the functional material in the pattern. This local field may be advantageously produced by using an optical fiber-based split-tip proximal probe alone, or by a combination of at least two sub-micrometer tips selected from the group consisting of an atomic force microscope tip, a scanning tunneling microscope tip, a near-field scanning optical microscope tip, a micro-pipette tip, an optical fiber tip, and a split-tip proximal probe. In another embodiment, the dip-pen may be a fountain pen with a sub-micrometer tip. The pen can be used to write a dot, a line or any complex-shape pattern.

### BRIEF DESCRIPTION OF THE DRAWING

FIG. 1. Schematic of a conventional dip pen nano-lithography process.

FIG. 2. A schematic representation of a field-assisted dip pen nano-lithography apparatus used to deposit a patterned thin film of a functional material or a monolayer, (A) one tip 64 serves as a dip pen tip while the two tips, 62 & 64 in combination, provide a strong local electric field; (B) the same tip serves dual purposes.

FIG. 3. (A) Schematic of a split-tip proximal probe as a source for generating a highly localized, strong electric field and (B) Schematic of a split-tip proximal probe as a source of localized magnetic field that serves to orient magnetic molecules.

FIG. 4. A schematic representation of an apparatus used to deposit a patterned thin film of a functional material and to provide a localized electric field for the polarization of the material: (A) The localized electric field is parallel to the target surface plane; (B) The localized electric field is inclined at an angle relative to the target surface.

### DETAILED DESCRIPTION OF THE PREFERRED EMBODIMENTS

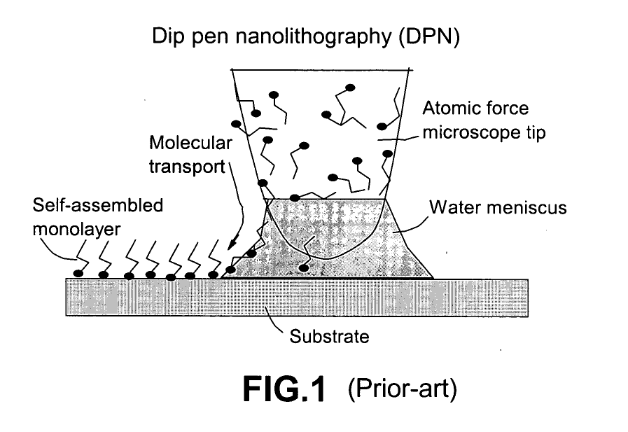

As shown in FIG. 1, state-of-the-art dip pen nano-lithography (DPN) involves delivering molecules from a sub-micrometer tip surface to a substrate of interest in a positive printing mode. In a DPN apparatus, a solid substrate is utilized as the “paper” and an atomic force microscope (AFM) tip as the “pen”. A scanning tunneling microscope (STM) or a micro-pipette tip may also be used. The tip is coated with a patterning compound (the “ink”), and the coated tip is brought to contact with the substrate so that the patterning compound is transferred to the substrate to produce a desired pattern. The molecules of the patterning compound are delivered from the tip to the substrate by the mechanism of capillary transport. In this conventional DPN process, the molecules slide from the perimeter of an AFM tip, migrate through a water meniscus, and then land onto a substrate. This is a simple and effective way of producing a pattern of a desired compound or of several different compounds.

This simple scheme has a major drawback, nevertheless. The molecules sliding down do not necessarily pack themselves into a well-organized structure with a well-controlled preferred orientation. This is due to no intrinsic mechanism that is used to promote or facilitate the function of self-assembly. When a preferred molecular orientation is indeed obtained in some cases, this orientation is normally perpendicular to the substrate surface and can not be varied or tailor-made.

The present invention provides an effective way to overcome this drawback. This invention is made due to our recognition that most of the molecules suitable for forming a self-assembled manolayer (SAM) or a Langrnuir-Blodget film are polar in nature. This is in the sense that one end of the molecule or functional group is slightly positively charged and the other end negatively charged. This polarity makes it possible to control the molecular orientation using a local electric field. Additionally, in the cases of ferromagnetic molecules or single-molecular magnets for spin electronics, these molecules exhibit a preferred spin or Bohr magneton orientation that is sensitive to the presence of a magnetic field. The orientation of these molecules can be controllably varied by using a local magnetic field.

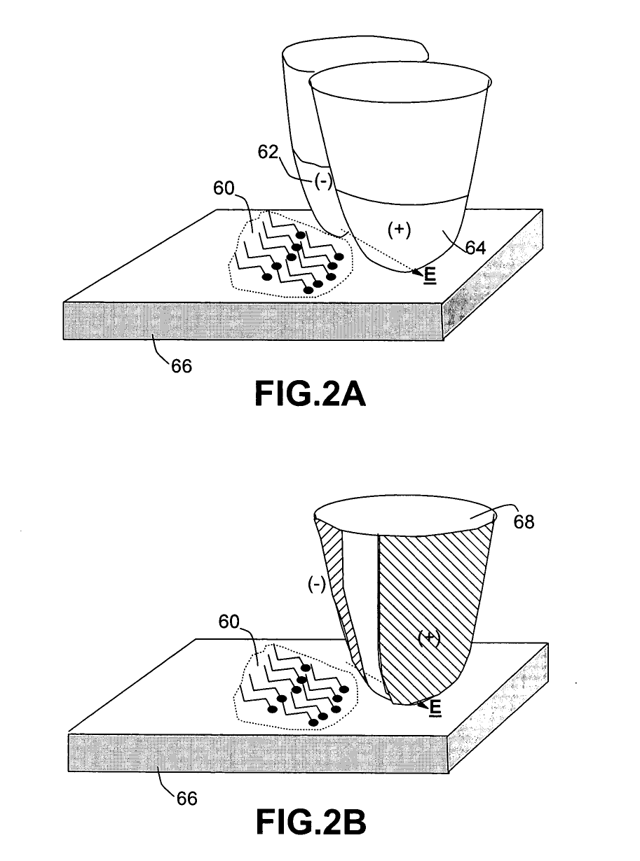

Referring to FIG. 2A, one or both of the AFM-type tips 62,64 may be used as a dip pen for delivering the molecules onto a substrate (target surface 66), analogous to the conventional dip-pen nano-lithography procedure. In addition, these two tips could constitute a pair of electrodes, providing a local electric filed to promote the formation of a preferred molecular orientation in a domain 60 or phase. In this case, both tips can be coated with a metal with the two tips electrically supplied with a voltage V.

Alternatively, as shown in FIG.2B, only one tip is used that serves dual purposes of providing the molecule-delivering function and the molecule-orientating function. The two electrodes of a voltage are deposited on two sides of an AFM-type or a split-tip optical fiber tip 68. In both FIG. 2A and FIG. 2B, the electric field is designed to lie substantially parallel to the target surface so that the molecular orientation in the domain is also parallel to the target surface. However, the relative position of the two electrodes and the orientation of a fiber tip can be readily varied, as desired, to vary the field orientation.

Hence, one preferred embodiment of the present invention is a dip pen-based direct-write micro- or nano-fabrication method capable of directly depositing a functional material with a preferred orientation in the form of a patterned thin film (e.g., a self-assembled monolayer, SAM) onto a target surface (a solid substrate). The method includes the following steps: (1) forming a precursor fluid to the functional material with the fluid containing a liquid component; (2) operating a sub-micrometer tip to discharge the precursor fluid onto the target surface, by bringing the tip to contact the target surface, so as to produce a desired pattern of deposited functional material in sub-micrometer dimensions; and (3) during the pattern-producing step, subjecting the deposited material to a highly localized electric or magnetic field for attaining a preferred orientation in at least a portion of the functional material in the pattern.

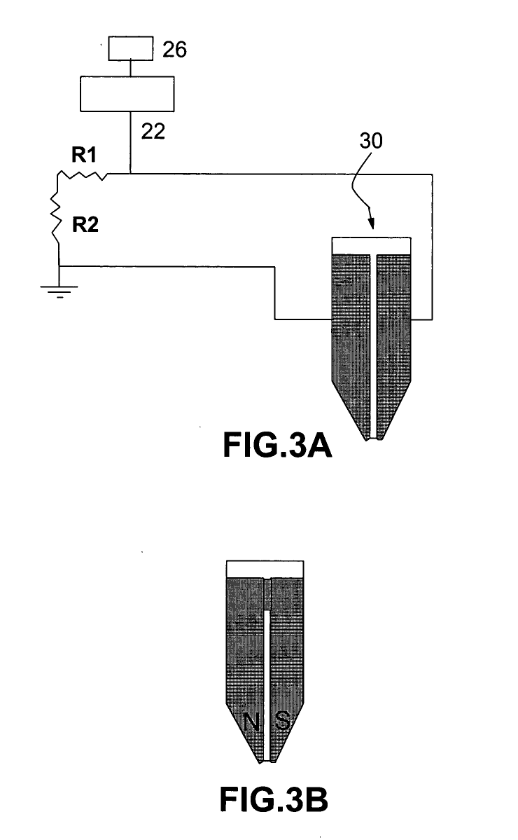

Preferably, the localized electric field is generated by a split-tip probe (FIG.3A). In one preferred embodiment, the split-tip probe consists of two electrically isolated and independently contacted metal electrodes deposited on opposite sides of a tapered optical fiber, similar to those used for near-field scanning optical microscopy (NSOM). The probe used in the present invention is fabricated using similar processes as the NSOM tips. Flat-ended and sharp-tipped optical fibers may be produced by using pulling and chemical etching methods, respectively. The fabrication of split-tip probes is a known art in the field of NSOM (e.g., see Mufei Xiao, et al. “Fabrication of probe tips for reflection SNOM,” Journal of Vacuum Sci. Tech. B15 (1997) 1516 and P. Hoffmann, et al. “Comparison of mechanically drawn and protection layer chemically etched optical fiber tips,” Ultramicroscopy, 61 (1995) 165.). Once the fiber is shaped, metal is coated on one side of the fiber to form one electrode. Then, the fiber is rotated 180° so that the opposite side can be coated with the same or different metal to form another electrode. This forms a split metal structure with the two metal sides electrically isolated. Copper, aluminum, gold or any metallic elements or alloys can be deposited as the electrodes. The electric field is provided through the high voltage DC source when the solution is being continuously transferred from a tip to a target surface. Temperature of the deposited material is adjusted as desired. It is advantageous to use a temperature that provides a high rate of solvent removal if a solvent is involved in the process.

The optical fiber end is sized from several hundred nanometers (nm) down to approximately 10 nm. Assume that the two oppositely positioned electrodes can be simulated as a parallel-plate capacitor, the electric field strength may be estimated as follows. With 1 volt applied across the electrodes that are 10 nm apart, a field strength of (IV/(10×10⁻⁹ m)=10⁸ V/m) is obtained. This implies that an extremely high-strength, and localized electric field is readily available by using a split-tip probe. This capability to generate strong, localized electric field for orienting polar molecules has not been, up to this point of time, reported for use in dip pen nano-lithography-based direct-write technology.

A split-tip type probe may also be made to produce a highly localized magnetic field if a strong magnet material is deposited onto opposite sides of the sharp tip of a chemically etched optical fiber (FIG. 3B). In this case, one side has a N pole while the opposite side has a S pole. Such a highly localized magnetic field provides a great improvement to the resolution (reduced magnetic domain sizes), making it possible to deposit functional elements (with preferred orientations) on ultra-small scales (micron or nanometer). A localized magnetic filed may also be produced by a micron-scale solenoid coil supplied with an electric current. Magnetic materials may be an organic or inorganic ferromagnetic and ferrimagnetic material, which is dissolved in a solvent to form a solution. Once dip pen-transferred to a target surface, the liquid or solvent is at least partially removed while the material fluid is subjected to the orientation treatment under the influence of the localized magnetic field.

Two examples are herein presented for the mere purpose of illustrating the essential steps of the invented method, as follows:

### EXAMPLE 1

### The Deposition of 1-octadecanethiol (ODT) to gold (Au) Surfaces

Example 1 involves deposition of ODT on a gold substrate. The procedure involved bringing an ODT-coated optical fiber tip into contact with a sample surface. The ODT molecules flowed from the fiber tip to the sample by capillary action. An optical fiber tip was sputter-coated with a thin gold electrode of 20 nm thick (the first electrode). The gold-plated fiber tip was then tentatively coated with ODT by dipping the fiber into a saturated solution of ODT in acetonitrile for 1 minute. A second optical fiber tip, coated with gold, serves as the second electrode which, in combination with the first electrode, provides a high electric field along a direction parallel to the line defined by the two tips. The dip pen nano-lithography process involved raster scanning such a tip across a 1 μm×1 μm section of a Au substrate positioned on a nano-positioning stage. Formation of high-quality self-assembled monolayers (SAMs) with a desired orientation occurred when the deposition process was carried out on the Au surface.

### EXAMPLE 2

Poly (vinylidene fluoride), PVDF, is a polarizable material which is used herein as an example. The method begins by first dissolving PVDF in a suitable amount of solvent to form a solution. Approximately 4% by weight of PVDF was dissolved in 96% of tricresylphosphate. A capacitor grade PVDF available from Kureha Kagoku Kogko Kabishiki Kaisha was used. Some of the solvent was vaporized to reduce the solvent content of the solution. As shown in FIG. 2B, the solution of PVDF was coated onto a dip pen (such as 68 in FIG. 2B) with additional amount of the solvent being allowed to vaporize The solution was delivered onto a target surface (a quartz) to form a domain of PVDF molecules with a preferred orientation. The procedure was repeated and continued until a PVDF film of a predetermined pattern was deposited. Both the dip pen and the target surface were placed in a suitable vacuum oven. The PVDF solution deposited, in small micrometer- and nanometer-scale regions, was subjected to a localized electric field produced between two closely positioned electrodes (e.g., on two sides of an optical fiber based split-tip probe 30 in FIG.3A) while the remaining solvent was removed. The electrodes are equipped with an appropriate DC source 22 controlled by a DC voltage ramping unit 26 (FIG. 3A).

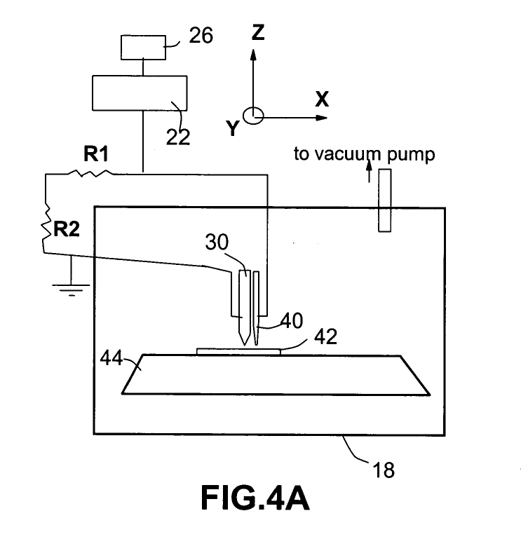

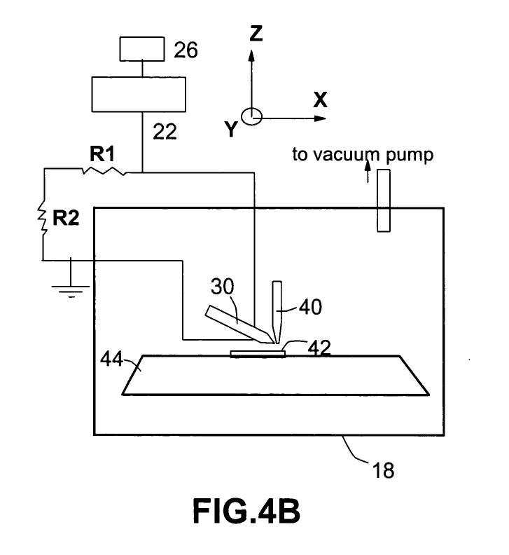

It may be noted that a micro- or nano-fabrication system can make use of a multiplicity (2 or more) of split-tip types of probes and/or AFM-type probes to produce localized electric and/or magnetic fields. These probe tips are preferably arranged in a regular-interval array for easier control. Hundreds or thousands of tips could be used to produce a massively parallel dip-pen nano-lithography system for much improved fabrication speed. FIG. 4A and 4B show only two tips, 30 and 40, but any number of dip pen tips and/or field electrode tips may be used.

Different tips can be used to transfer different types of molecules for a multi-material deposition. These materials may contain a composition selected from the group consisting of a piezo-electric, pyroelectric, light-emitting, light-sensing, solar cell, sensor, actuator, electro-optic logic, spin material, magnetic, thermo-electric, electromagnetic wave emission, transmission or reception elements, electronically addressable ink, and a combination thereof. In order to fabricate a MEMS device, several of these materials may be deposited.

During the liquid-removing step, where necessary, the liquid (solvent) content can be reduced during the polarization by passing a flow of a suitable gas (e.g., nitrogen) over the surface of the deposited film. Alternatively, a vacuum pump may be utilized to pump out the vaporized solvent continuously. The temperature at which the orientation-inducing process is carried out depends upon the desired rate at which a preferred orientation is achieved, the material used, the solvent used, the equipment available for field creation, the desired level of solvent wished to be retained in the final material and other factors. A deposition temperature of in the range of 60°- of 90° C. was found to give satisfactory results for PVDF.

A proper intensity of the electric field used can be selected to provide efficient control over molecular orientation. However, it is preferably kept below the range at which substantial dielectric breakdown of the material being treated occurs. An electrical field of 250 KV/cm (2.5×10⁷ V/m) was found to be satisfactory to induce an orientation in PVDF.

As shown in FIG. 4A, the method involves intermittently or continuously transferring a fluent material composition (e.g., a PVDF-solvent solution) coated on a dip-pen tip 40 to a target surface 42 of a support member 44. During this procedure, the target surface and the dip-pen tip are moved (preferably under the control of a computer and a controller/indexer) with respect to each other along selected directions in a predetermined pattern on an X-Y plane defined by first (X-) and second (Y-) directions and along the Z-direction perpendicular to the X-Y plane. The three mutually orthogonal X-, Y- and Z-directions form a Cartesian coordinate system. These relative movements are effected so that the material composition can be deposited essentially point by point according to a computer-aided design (CAD) drawing of a micro- or nano-device. The system may be enclosed in a controlled-atmosphere or vacuum chamber 18.

As shown in FIG.4B, one tip 30 is tilted at an angle so that the local electric field may be inclined at angle with respect to the target surface plane 42. The molecules delivered from the tip 40 will exhibit a preferred orientation substantially parallel to the field direction.

The scanning probe microscope (SPM) tip (e.g., AFM, STM, or NSOM) or a optical fiber tip is used to deliver a patterning compound to a substrate of interest. Any patterning compound can be used, provided it is capable of modifying the substrate to form stable surface structures. Stable surface structures are formed by chemisorption of the molecules of the patterning compound onto the substrate or by covalent linkage of the molecules of the patterning compound to the substrate.

A wide range of polymeric materials can be used in practicing this invention. Although a preferred material for the purpose of obtaining a preferred molecular orientation to achieve a desired level of piezo-electric or pyroelectric response, is poly(vinylidene fluoride), copolymers of vinylidene fluoride are also useful materials. These include vinylidene fluoride copolymers with vinyl fluoride, trifluoroethylene, tetrafluoroethylene, vinyl chloride, methylmethacrylate, and others. The vinylidene fluoride content can vary in the range of from about 30% by weight to about 95% by weight. Other polymers which can be used are polyvinylchloride, polymethylacrylate, polymethylmethacrylate, vinylidene cyanide/vinyl acetate copolymers, vinylidene cyanide/vinyl benzoate copolymers, vinylidene cyanide/isobutylene copolymers, vinylidene cyanide/methyl methacrylate copolymers, polyvinylfluoride, polyacrylonitrile, polycarbonate, and nylons such as Nylon-7 and Nylon-11, natural polymers such as cellulose and proteins, synthetic polymers such as derivatives of cellulose, such as esters and ethers, poly (γ-methyl-L-glutamate), and the like. In addition, polarizable materials which are soluble ceramic materials and capable of forming polar crystals or glasses can be used together with an appropriate polarization solvent for a particular soluble ceramic material used.

A variety of organic solvents can be used depending upon the material used in the polarization, cost and safety consideration, equipment used, and other factors. Tricresylphosphate has been found to be a suitable solvent for PVDF and many copolymers of vinylidene fluoride. Dibutyl phthalate can also be used as the solvent for these vinylidene polymers. For nylon-7 and nylon-11, 2-ethyl-1,3-hexanediol can be used.

Ferromagnetic materials that can be subjected to orientation treatments include, but not limited to, decamethylferrocene-TCNE charge transfer compound, zwitterionic copolymers and those having the general formula A:N—B (where A:N— is α-substituted cyclic amine and B is α-substituted cyclic radical), as disclosed by Leriche, et al. (U.S. Pat. No. 6,262,306, Jul. 17, 2001).

Many suitable non-polymeric patterning compounds can be used for practicing the present invention. Mirkin, et al. (U.S. Pat. No. 6,635,311, Oct. 21, 2003) have provided a good list: (a) Compounds of the formula R₁SH, R₁SSR R₂, R₁SR₂, R₁SO₂H, (R₁)₃P, R₁NC, R₁CN, (R₁)₃N, R₁COOH, or ArSH can be used to pattern gold substrates; (b) Compounds of formula R₁SH, (R₁)₃N, or ArSH can be used to pattern silver, copper, palladium and semiconductor substrates; (c) Compounds of the formula R₁NC, R₁SH, R₁SSR₂, or R₁SR₂ can be used to pattern platinum substrates; (d) Compounds of the formula R₁SH can be used to pattern aluminum, TiO₂, SiO₂, GaAs and InP substrates; (e) Organosilanes, including compounds of the formula R₁SiCl₃, R₁Si(O R₂)₃, (R₁COO)₂, R₁CH═CH₂, R₁Li or R₁MgX, can be used to pattern Si, SiO₂ and glass substrates; (f) Compounds of the formula R₁COOH or R₁CONHR₂ can be used to pattern metal oxide substrates; (g) Compounds of the formula R₁SH, R₁NH₂, ArNH₂, pyrrole, or pyrrole derivatives wherein R₁ is attached to one of the carbons of the pyrrole ring, can be used to pattern cuprate high temperature superconductors; (h) Compounds of the formula R₁PO₃H₂ can be used to pattern ZrO₂ and In₂O₃/SnO₂ substrates; (i) Compounds of the formula R₁COOH can be used to pattern aluminum, copper, silicon and platinum substrates; (0) Compounds that are unsaturated, such as azoalkanes (R₃NNR₃) and isothiocyanates (R₃NCS), can be used to pattern silicon substrates; and (k) Proteins and peptides can be used to pattern, gold, silver, glass, silicon, and polystyrene. In the above formulas: R₁ and R₂ each has the formula X(CH₂)n and, if a compound is substituted with both R₁ and R₂, then R₁ and R₂ can be the same or different; R₃ has the formula CH₃(CH₂)n; n is 0-30; Ar is an aryl; X is —CH₃, —CHCH₃, —COOH, —CO₂(CH₂)ₘCH₃, —OH, —CH₂OH, ethylene glycol, hexa(ethylene glycol), —O(CH₂)ₘCH₃, —NH₂, —NH(CH₂)ₘNH₂, halogen, glucose, maltose, fullerene C60, a nucleic acid (oligonucleotide, DNA, RNA, etc.), a protein (e.g., an antibody or enzyme) or a ligand (e.g., an antigen, enzyme substrate or receptor); and m is 0-30.

The deposited pattern can contain a dot, a line, an array of dots or lines, etc. The deposited functional materials or self-assembled monolayers can be physically absorbed (or simply anchored to) or chemically bonded (including chemisorbed) to a substrate, depending upon the types of molecules delivered and the surface chemical state of the substrate.

Another embodiment of the present invention is a direct-write micro- or nano-lithography method for depositing a functional material onto a target surface, using a fluid-filled micro-pipette dip pen or fountain pen with a sub-micrometer or nanometer-size orifice. The method includes the steps of (1) forming a precursor fluid to the functional material with the fluid containing a liquid component; (2) providing a dispensing nozzle comprising a tip with a sub-micrometer orifice and a liquid chamber supplying the precursor fluid to the orifice; (3) contacting the tip with the target surface so that the precursor fluid is delivered to the target surface so as to produce a desired pattern of the functional material in sub-micrometer dimensions; and (4) during the pattern-producing step, subjecting the deposited material to a highly localized electric or magnetic field for attaining a preferred orientation in at least a portion of the functional material. Micro-pipette is known in the art; e.g., M. H. Hong, et al., “Scanning nanolithography using a material-filled nanopipette,” Appl. Phys. Lett., 77 (16) (2000) 2640-46.

The liquid chamber is equipped with a pressurizing means to provide a back pressure for overcoming the capillarity force, which is relatively high for a nanometer-scale orifice channel. We have found it advantageous to supply the chamber with a back pressure so as to allow a droplet of the precursor fluid to protrude out of the orifice tip but still remain attached to the tip due to surface tension. This droplet will not be discharged from the orifice until the tip is brought in contact with the target surface (like a fountain pen). This is in contrast to the case of inkjet printing wherein a piezo-electric or thermal bubble-induced pulse acts to drive off (print out) the droplet. Again, a local field for inducing a molecular orientation may be produced by using a split-tip proximal probe alone, or by a combination of at least two sub-micrometer tips selected from the group consisting of an atomic force microscope tip, a scanning tunneling microscope tip, a near-field scanning optical microscope tip, a micro-pipette tip, an optical fiber tip, and a split-tip proximal probe.

DPN is known to be a simple but powerful method for transporting molecules from AFM, optical fiber, or micro-pipette tips to substrates at resolutions comparable to those achieved with much more expensive and sophisticated competitive lithographic methods, such as electron-beam lithography. Further, DPN is a useful tool for creating and functionalizing micro-scale and nano-scale structures. The presently invented field-assisted DPN method provides added advantages in that (a) the molecular orientations can be better-controlled, (b) a stronger level of molecular orientation can tailor-made, and (c) the orientation can be readily varied from point to point in a sub-micrometer or nanometer structure. The improved DPN can be used in the fabrication of microsensors, microreactors, combinatorial arrays, micromechanical systems, microanalytical systems, biosurfaces, biomaterials, microelectronics, micro-optical systems, and nano-electronic devices.

1. A direct-write micro- or nano-lithography method for depositing a functional material with a preferred orientation onto a target surface, said method comprising:
(1) forming a precursor fluid to said functional material, said fluid containing a liquid component;
(2) operating a sub-micrometer tip to discharge said precursor fluid onto said target surface, by bringing said tip to contact said surface, so as to produce a desired pattern of deposited functional material in sub-micrometer dimensions; and
(3) during said pattern-producing step, subjecting the deposited material to a highly localized electric or magnetic field for attaining a preferred orientation in at least a portion of said functional material.

2. The method of claim 1, wherein said precursor fluid comprises a compound selected from one of the following groups: (a) Compounds of the formula R₁SH, R₁SSR₂, R₁SR₂, R₁SO₂H, (R₁)₃P, R₁NC, R₁CN, (R₁)₃N, R₁COOH, R₁CONHR₂, R₁NH₂, ArNH₂ or ArSH; (b) Organosilanes, including compounds of the formula R₁SiCl₃, R₁Si(O R₂)₃, (R₁COO)₂, R₁CH═CH₂, R₁Li or R₁MgX; (c) pyrrole and pyrrole derivatives wherein R₁ is attached to one of the carbons of the pyrrole ring; (d) Compounds of the formula R₁PO₃H₂; (j) Unsaturated compounds including azoalkanes (R₃NNR₃) and isothiocyanates (R₃NCS); and (k) Proteins and peptides; wherein R₁ and R₂ each has the formula X(CH₂)n and, if a compound is substituted with both R₁ and R₂, then R₁ and R₂ can be the same or different; R₃ has the formula CH₃(CH₂)n; n is 0-30; Ar is an aryl; X is —CH₃, —CHCH₃, —COOH, —CO₂(CH₂)ₘCH₃, —OH, —CH₂OH, ethylene glycol, hexa(ethylene glycol), —O(CH₂)ₘCH₃, —NH₂, —NH(CH₂)ₘNH₂, halogen, glucose, maltose, fullerene C60, a nucleic acid (oligonucleotide, DNA, RNA, etc.), a protein (e.g., an antibody or enzyme) or a ligand; and m is 0-30.

3. The method of claim 1, wherein said desired pattern comprises a dot.

4. The method of claim 1, wherein said desired pattern comprises a line.

5. The method of claim 1, wherein said desired pattern comprises a self-assembled monolayer.

6. The method of claim 1, wherein said compound after deposition is a surface structure anchored to said target surface.

7. The method of claim 1, wherein said compound is chemisorbed to the target surface upon discharge.

8. The method of claim 1, wherein said sub-micrometer tip comprises a tip selected from the group consisting of an atomic force microscope tip, a scanning tunneling microscope tip, a near-field scanning optical microscope tip, a micro-pipette tip, an optical fiber tip, and a combination thereof.

9. The method as defined in claim 1, wherein said pattern comprises at least a micrometer- or nanometer-scaled region of said functional material.

10. The method as defined in claim 1, wherein said highly localized electric or magnetic field is substantially focused in a region smaller than 1 μm in size.

11. The method as defined in claim 1, wherein said highly localized electric or magnetic field is generated by using a split-tip proximal probe.

12. The method as defined in claim 1, wherein said highly localized electric or magnetic field is generated by using two sub-micrometer tips selected from the group consisting of an atomic force microscope tip, a scanning tunneling microscope tip, a near-field scanning optical microscope tip, a micro-pipette tip, an optical fiber tip, and a split-tip proximal probe.

13. The method as defined in claim 1, wherein said target surface is preheated or precooled to a desired temperature.

14. The method as defined in claim 1, wherein said target surface is exposed to a controlled atmosphere.

15. The method as defined in claim 14, wherein said controlled atmosphere is selected from a group consisting of a vacuum, an inert gas, a reactive gas, and a combination of an inert gas and a reactive gas.

16. The method as defined in claim 1, wherein said pattern-producing step comprises removing at least a portion of said liquid component by operating a device selected from the group consisting of a ventilation fan, a vacuum pump, a hot air blower, a heater, and a combination thereof.

17. The method as defined in claim 1, wherein said functional material is selected from the group consisting of a piezo-electric material, a pyroelectric material, a ferro-electric material, a non-linear optic material, a conducting polymer, a ferromagnetic material, a ferri-magnetic material, an anti-ferromagnetic material, a liquid crystal material, and a combination thereof.

18. The method of claim 1, wherein said sub-micrometer tip comprises a plurality of tips arranged in a desired geometric pattern.

19. The method of claim 1, wherein said sub-micrometer tip comprises at least a split-tip proximal probe and at least one atomic force microscope tip, a scanning tunneling microscope tip, a near-field scanning optical microscope tip, or a micro-pipette tip.

20. A direct-write micro- or nano-lithography method for depositing a functional material onto a target surface, said method comprising:
(1) forming a precursor fluid to said functional material, said fluid containing a liquid component;
(2) providing a dispensing nozzle comprising a tip with a sub-micrometer orifice and a liquid chamber supplying said precursor fluid to said orifice;
(3) contacting said tip with said target surface so that the precursor fluid is delivered to said target surface so as to produce a desired pattern of said functional material in sub-micrometer dimensions; and
(4) during said pattern-producing step, subjecting the deposited material to a highly localized electric or magnetic field for attaining a preferred orientation in at least a portion of said functional material.

21. The method of claim 20, wherein said highly localized electric or magnetic field is generated by using a split-tip proximal probe.

22. The method of claim 20, wherein said dispensing nozzle comprises a plurality of tips arranged in a desired geometric pattern.

23. The method of claim 20, wherein said dispensing nozzle comprises at least one tip with a sub-micrometer orifice and at least a split-tip proximal probe.

24. The method as defined in claim 20, wherein said highly localized electric or magnetic field is generated by using two sub-micrometer tips selected from the group consisting of an atomic force microscope tip, a scanning tunneling microscope tip, a near-field scanning optical microscope tip, a micro-pipette tip, an optical fiber tip, and a split-tip proximal probe.

25. The method of claim 20, wherein said liquid chamber is supplied with a pressure sufficient to produce a droplet of said fluid attached to said orifice.
